(19) United States
(12) Patent Application Publication
(10) Pub. No.: US 2025/0359012 A1
(43) Pub. Date: Nov. 20, 2025

(54) SEMICONDUCTOR DEVICE AND MANUFACTURING METHOD THEREFOR, MEMORY AND ELECTRONIC EQUIPMENT

(71) Applicant: BEIJING SUPERSTRING ACADEMY OF MEMORY TECHNOLOGY, Beijing (CN)

(72) Inventors: Yansan MA, Beijing (CN); Jing ZHANG, Beijing (CN); Long HUANG, Beijing (CN); Wei YU, Beijing (CN); Jiating YU, Beijing (CN); Guilei WANG, Beijing (CN); Chao ZHAO, Beijing (CN)

(73) Assignee: BEIJING SUPERSTRING ACADEMY OF MEMORY TECHNOLOGY, Beijing (CN)

(21) Appl. No.: 18/697,761

(22) PCT Filed: Oct. 16, 2023
(86) PCT No.: PCT/CN2023/124779

§ 371 Date: Jul. 28, 2025

(30) Foreign Application Priority Data
Apr. 27, 2023 (CN) 202310468466.3

(51) Int. Cl. H10B 12/00

(52) U.S. Cl. CPC H10B 12/30; H10B 12/03

(57) ABSTRACT

A semiconductor device includes one or at least two capacitors stacked along a direction perpendicular to a substrate. At least one of the capacitors includes a first plate and a second plate, and a dielectric layer between the first plate and the second plate. The first plate includes a first body structure and at least two first branch layers arranged at intervals along a direction perpendicular to the substrate, the first body structure includes a first conductive layer and a second conductive layer alternately stacked along the direction perpendicular to the substrate, the first plate further includes a groove between adjacent first branch layers, the groove extends along a direction parallel to the substrate, and at least part of the dielectric layer and at least part of the second plate are within the groove. Implementing all of the above improves the capacity of the capacitor.

### CROSS-REFERENCE TO RELATED APPLICATIONS

This application is the U.S. national phase of PCT Application No. PCT/CN2023/124779 filed on Oct. 16, 2023, which claims priority to Chinese patent application number 202310468466.3 filed on Apr. 27, 2023, the contents of both of which are hereby incorporated herein by reference in their entireties.

### TECHNICAL FIELD

Embodiments of the present disclosure relate to, but are not limited to, semiconductor technology, in particular to a semiconductor device and a method for manufacturing the semiconductor device, a memory, and an electronic equipment.

### BACKGROUND

With the development of Dynamic Random Access Memory (DRAM) technology, 1T1C structure has reached its limit due to its large storage capacitor.

### SUMMARY

The is a summary of subject matter described in detail herein. This summary is not intended to limit the scope of protection of the claims.

An embodiment of the present disclosure provides a semiconductor device, including:
one or at least two capacitors stacked along a direction perpendicular to a substrate; wherein at least one of the capacitors includes a first plate and a second plate, and a dielectric layer between the first plate and the second plate;
the first plate includes a first body structure and at least two first branch layers, wherein the at least two first branch layers are arranged at intervals along a direction perpendicular to the substrate, the first body structure includes a first conductive layer and a second conductive layer alternately stacked along the direction perpendicular to the substrate, the first plate further includes a groove located between adjacent first branch layers, the groove extends along a direction parallel to the substrate, and at least part of the dielectric layer and at least part of the second plate are located in the groove.

In some embodiments, the materials of the first conductive layer and the second conductive layer are different, the second conductive layer is connected with adjacent first conductive layers, and the first branch layer is connected with the first conductive layers.

In some embodiments, the first conductive layer and the second conductive layer have different etching selectivity ratios;
the first branch layers and the first conductive layer form an integrated structure;
the groove and the second conductive layer are located in a same film layer, and bottom of the groove is an end face of the second conductive layer.

In some embodiments, the depth of grooves in different layers is the same in the first plate.

In some embodiments, the second plate includes a second body structure and at least two second branch layers located on the second body structure, the at least two second branch layers are arranged at intervals along a direction perpendicular to the substrate, at least one of the second branch layers is disposed in a corresponding groove to fill the groove.

In some embodiments, the first plate includes an upper surface and a lower surface that are oppositely disposed, and two side surfaces connecting the upper surface with the lower surface, the groove penetrates through the side surface of the first plate, the groove is on the side surface of the first plate to expose a side surface of the second branch layer.

In some embodiments, at least two of the capacitors are stacked at intervals in the direction perpendicular to the substrate; in the direction perpendicular to the substrate, second plates of adjacent capacitors are connected to form an integrated structure.

In some embodiments, at least two of the capacitors are stacked at intervals in the direction perpendicular to the substrate; in the direction perpendicular to the substrate, materials of the first conductive layers of the first plates of different capacitors are the same, and materials of the second conductive layers of the first plates of the different capacitors are the same.

In some embodiments a material type of the first conductive layer includes one of the followings: metal, alloy, metal nitride and metal oxide conductor; a material type of the second conductive layer includes one of the followings: metal, alloy, metal nitride, and metal oxide conductor.

An embodiment of the present disclosure further provides a memory including any of the semiconductor devices described above.

In some embodiments, the memory includes a single-layer memory cell or a memory cell of a plurality of stacked layers, and the memory cell includes a transistor, the transistor includes a first electrode, and a capacitor of the semiconductor device is connected with the first electrode of the transistor.

In some embodiments, the first electrode and a first body structure of a first plate of the capacitor form an integrated structure.

In some embodiments, the first electrode is an extended portion of the first body structure in a direction away from the second plate.

In some embodiments, the transistor further includes a second electrode, a gate electrode and a semiconductor layer, the gate electrode extends along the direction perpendicular to the substrate, the semiconductor layer surrounds the gate electrode and is insulated from the gate electrode, the first electrodes and the second electrode are arranged at intervals on the semiconductor layer, and the semiconductor layer includes a channel extending along the direction parallel to the substrate.

An embodiment of the disclosure further provides an electronic equipment, which includes any one of the memory cells described above.

An embodiment of the present disclosure also provide a method for manufacturing a semiconductor device, wherein the semiconductor device includes one or at least two capacitors stacked in a direction perpendicular to a substrate; at least one of the capacitors includes a first plate and a second plate, and a dielectric layer between the first plate and the second plate; the first plate includes a first body structure and at least two first branch layers, the at least two first branch layers are arranged at intervals along the direction perpendicular to the substrate, the first body structure includes a first conductive layer and a second conductive layer alternately stacked along the direction perpendicular to the substrate; the method for manufacturing the semiconductor device includes:
providing a substrate, sequentially forming a first conductive thin film and a second conductive thin film arranged alternately on the substrate, wherein the first conductive thin film and the second conductive thin film have different etching selectivity ratios;
etching and removing a part of the second conductive thin film in a direction parallel to the substrate, forming the retained second conductive thin film into the second conductive layer, and forming the part of the second conductive thin film that has been etched and removed into a groove, wherein the groove extends along a direction parallel to the substrate;
forming a part of the first conductive thin film into the first branch layers, wherein the groove is located between adjacent first branch layers; forming a part of the first conductive thin film into a first conductive layer;
forming a dielectric layer, wherein at least a part of the dielectric layer is formed on an inner wall of the groove; and
forming a second plate, wherein at least a part of the second plate is located in the groove.

In some embodiments, grooves of the capacitors of different layers are formed by a single etching process in a direction perpendicular to the substrate.

Embodiments of the present disclosure provide a semiconductor device, a method for manufacturing the semiconductor device, a memory and an electronic equipment. By arranging first branch layers at intervals along a direction perpendicular to the substrate, grooves are located between adjacent first branch layers, so that at least a part of the second plate is located in the grooves, an area where the second plate and the first plate are facing each other is increased, and capacity of the capacitor is improved.

Other features and advantages of the present disclosure will be set forth in the following specification, and moreover, partially become apparent from the specification, or are understood by implementing the present disclosure. The objectives and advantages of the present disclosure may be achieved through structures particularly pointed out in the specification and the drawings.

Other aspects may be understood upon reading and understanding the drawings and detailed description.

### BRIEF DESCRIPTION OF DRAWINGS

The attached drawings are used to provide understanding of technical solutions of the present disclosure, and constitute a part of the specification. They are used together with the embodiments of the present disclosure to explain the technical solutions of the present disclosure, and do not constitute a restriction on the technical solutions of the present disclosure. The shape and size of each component in the drawings does not reflect true proportions and are intended to schematically explain contents of the present disclosure only.

FIG. 1A is a cross-sectional view of a memory taken along a direction perpendicular to a substrate according to an exemplary embodiment.

FIG. 1B is a cross-sectional view of a memory taken along a direction parallel to a substrate according to an exemplary embodiment.

FIG. 1C is a cross-sectional view of a capacitor of a semiconductor device taken along a direction perpendicular to a substrate according to an exemplary embodiment.

FIG. 2 is a schematic diagram after a first conductive thin film and a second conductive thin film are formed in a manufacturing process of a semiconductor device according to an exemplary embodiment.

FIG. 3 is a schematic diagram after grooves are formed in a manufacturing process of a semiconductor device according to an exemplary embodiment.

FIG. 4 is a schematic diagram after a dielectric layer is formed in a manufacturing process of a semiconductor device according to an exemplary embodiment.

### DETAILED DESCRIPTION

Embodiments of the present disclosure will be described in detail below with reference to the accompanying drawings. Embodiments of the present disclosure and features in the embodiments may be randomly combined with each other if there is no conflict.

Unless otherwise defined, technical terms or scientific terms used in the present disclosure shall have general meanings as understood by a person of ordinary skill in the art to which the present disclosure pertains.

Embodiments of the present disclosure are not necessarily limited to the dimensions shown in the drawings and the shapes and sizes of components in the drawings do not reflect true proportions. Further, the drawings schematically illustrate ideal examples, but embodiments of the present disclosure are not limited to shapes or values shown in the drawings.

Ordinal numerals such as “first”, “second” and “third” in the present disclosure are provided to avoid confusion between constituent elements, but do not indicate any order, quantity or importance.

In the present disclosure, for convenience, words and expressions indicating orientation or positional relationship such as “middle”, “upper”, “lower”, “front”, “rear”, “vertical”, “horizontal”, “top”, “bottom”, “inner” and “outer” are employed to explain the positional relationship of the constituent elements with reference to the accompanying drawings, they are employed for ease of description and simplification of the description only, but do not indicate or imply that the referred device or element must have a particular orientation, be constructed and operate in a particular orientation, and therefore cannot be construed as limitations on the present disclosure. The positional relationship of the constituent elements is appropriately changed according to the direction according to which each constituent element is described. Therefore, it is not limited to the words and expressions described in the present disclosure, and can be appropriately replaced according to the situation.

In the present disclosure, the terms “mounted”, “connected” and “connection” are to be understood broadly, unless otherwise expressly specified and defined. For example, a connection can be a fixed connection, a detachable connection, or an integrated connection; it can be a mechanical connection or an electrical connection; it can be direct connection, indirect connection through a middleware, or internal communication between two elements. For those of ordinary skills in the art, meanings of the above terms in the present disclosure may be understood according to actual situations.

In the present disclosure, a transistor refers to an element including at least three terminals, i.e., a gate electrode, a drain electrode, and a source electrode. A transistor has a channel region between a drain electrode (drain terminal, drain region, or drain) and a source electrode (source terminal, source region, or source), and a current can flow through the drain electrode, the channel region, and the source electrode. In the present disclosure, the channel region refers to a region through which the current mainly flows.

In the present disclosure, the first plate may be a drain electrode and the second plate may be a source electrode, or the first plate may be a source electrode and the second plate may be a drain electrode. Functions of the “source electrode” and the “drain electrode” are sometimes interchanged in the case of the use of transistors with opposite polarities or in the case of changes in the direction of the current in the operation of the circuit. Therefore, in the present disclosure, the “source electrode” and the “drain electrode” can be interchanged with each other.

In the present disclosure, “electrical connection” includes the case where the constituent elements are connected together by elements having certain electrical effects. There are no special restrictions on the “elements with certain electrical effects” as long as they can give and receive electrical signals between connected constituent elements. Examples of the “elements having certain electrical effects” include not only electrodes and wiring, but also switching elements such as transistors, resistors, inductors, capacitors, and other elements having various functions, etc.

In the present disclosure, “parallel” refers to approximately parallel or almost parallel, for example, refers to a state in which the angle formed by two straight lines is above −10 degrees and below 10 degrees, and therefore also includes a state in which the angle is above −5 degrees and below 5 degrees. In addition, “perpendicular” refers to “approximately perpendicular”, for example, refers to a state in which the angle formed by two straight lines is above 80 degrees and below 100 degrees, and therefore also includes a state in which the angle is above 85 degrees and below 95 degrees.

The “A and B are an integrated structure” in embodiments of the present disclosure may mean that there is no obvious boundary interface, such as obvious faults or gaps, viewed from the microstructure. Generally, the connected film layers formed by patterning on one film layer are an integrated structure. For example, A and B use a same material to form one film layer and simultaneously form a structure with a connection relationship through the same patterning process.

An embodiment of the present application provides a memory cell usable in a memory, the memory cell includes a capacitor connected with a transistor. The capacitor includes a first capacitive electrode and a second capacitive electrode, wherein a capacitive electrode connected with the transistor is a heterogeneous multilayer conductor, and heterogeneity in the heterogeneous multilayer conductor is formed of different materials, and the conductors formed of different materials have different etching selectivity ratios. In the capacitive electrode of heterogeneous multilayer conductor, the conductor of one material shrinks due to etching, and a groove is formed between two adjacent conductive layers of another material, and an exposed conductive layer in the groove is wrapped by a dielectric layer and the other capacitive electrode of the capacitor. Such capacitor can greatly improve a directly-facing effective surface area and capacitance between the two electrodes. At the same time, the heterogeneous multilayer conductor can effectively simplify the manufacturing process of the capacitor, and realize the capacitor with simple structure, easier miniaturization, simple process and lower manufacturing cost.

The capacitor of the present application may be suitable for application scenes of 1T1C memory cells or other scenes of memory cells with capacitors. In addition, the capacitor is suitable for both a single-layer memory cell and a memory cell with a plurality of stacked layers in which memories are stacked with each other. New structure and new process of the capacitor of the present application are illustrated in the following by taking a scene of a memory in 3D stacking of 1T1C as an example.

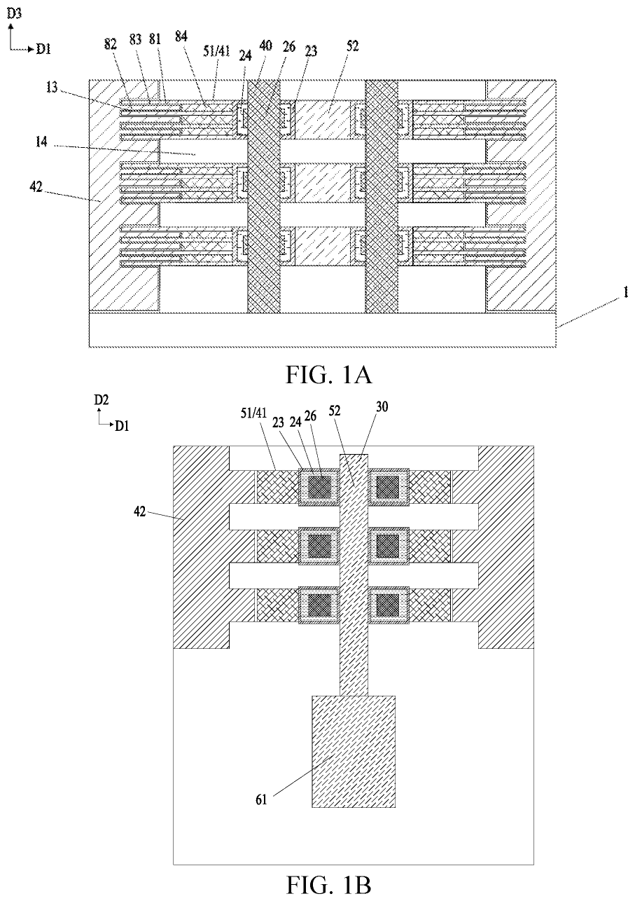

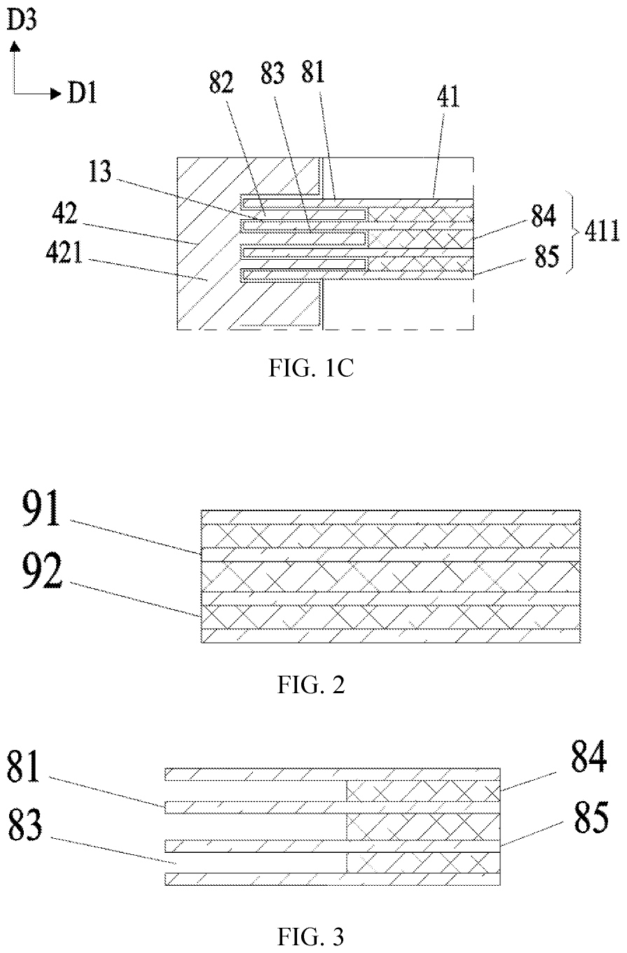

FIG. 1A is a cross-sectional view of a memory taken along a direction perpendicular to a substrate according to an exemplary embodiment. As shown in FIG. 1A, this embodiment provides a memory that may include a substrate 1, one or more memory cells stacked along the direction perpendicular to the substrate 1, and word lines 40 disposed on the substrate 1. The word lines 40 extend along the direction perpendicular to the substrate 1 and penetrate memory cells of different layers;
each memory cell may include a transistor and a capacitor, and the transistor includes a first electrode 51, a second electrode 52, a gate electrode 26 and a semiconductor layer 23. The gate electrode 26 is in a linear shape and extends along the direction perpendicular to the substrate 1, and the gate electrode 26 is connected with a word line 40. In the embodiment shown in FIG. 1A, the gate electrode is a part of the word line. The semiconductor layer 23 surrounds the gate electrode 26 or a sidewall of the word line 40 and is insulated from the gate electrode 26. A gate electrode insulation layer 24 is disposed between the gate electrode 26 and the semiconductor layer 23, and the gate electrode insulation layer 24 insulates the gate electrode 26 from the semiconductor layer 23. The semiconductor layer 23 is a film layer, and a main surface of the semiconductor layer 23 extends above a sidewall of the gate electrode 26 with the gate electrode insulation layer 24 disposed therebetween to form a surrounding semiconductor layer extending along the direction perpendicular to the substrate. The first electrode 51 and the second electrode 52 are horizontally arranged at intervals on the semiconductor layer 23 and are positioned on opposite sides of the gate electrode 26 in the first direction D1. At least part of the semiconductor layer 23 is positioned between the first electrode 51 and the gate electrode 26, and at least part of the semiconductor layer 23 is positioned between the second electrode 52 and the gate electrode 26, respectively. The semiconductor layer 23 includes a channel extending along a direction parallel to the substrate 1, such that the channel between the first electrode 51 and the second electrode 52 is a horizontal channel, and the first direction D1 is parallel to a plane where the substrate is located.

In an exemplary embodiment, a word line is a lead shared by a plurality of transistors stacked perpendicularly, and the lead is connected to or shared by gate electrodes of the transistors. In the stacked structure of FIG. 1A, the word line includes a longitudinally extending line shared by three stacked transistors. A gate electrode refers to a gate electrode of a transistor, and the gate electrode 26 is a part of the word line 40 in FIG. 1A. The word line generally extends along the longitudinal direction, but cross-sectional sizes at different positions of the word line may be the same or different. For example, a region of the word line corresponding to an effective channel of each transistor is an effective gate electrode, and a cross-section of the effective gate electrode may be larger or smaller than other regions on the word line, which is not specifically limited here in the present application. Said other regions may be regions that do not correspond to an effective channel of the transistors, such as regions between two longitudinally stacked transistors.

Since the word line is formed by filling a hole with a conductive material, the hole penetrating through the memory cells of each layer generally extend along the direction perpendicular to the substrate, but are not necessarily a hole with equal cross-section, and the word line forms a conductive line of similar shape according to a shape of the hole.

The memory according to this embodiment is at least partially arranged at intervals between semiconductor layers of transistors of adjacent layers in the direction perpendicular to the substrate 1, which can reduce or eliminate parasitic MOS between at least part of layers and improve device stability. Being arranged at intervals can be understood as: the adjacent semiconductor layers of the adjacent transistors are separated from each other, for example, the semiconductor layer formed on an inner wall of the hole is hollowed out or modified in the region between the adjacent semiconductor layers, so that the region cannot function as a semiconductor.

A horizontal channel means that a carrier transport direction in the channel is in a plane parallel to the substrate, but it is not limited to that the carrier transport direction must be one direction. In practical applications, the carrier transport direction generally extends along one direction, but locally, it is related to the shape of the semiconductor layer. In other words, the horizontal channel does not mean that it must extend in one direction in the horizontal plane, but may extend in different directions. For example, when the semiconductor layer is annular, a source contact region and a drain contact region on the annular semiconductor layer are parts of the annular ring. At this time, carriers generally extend along one direction from the source contact region to the drain contact region, but may not be along one direction locally. Apparently, the carrier transport direction in a plane parallel to the substrate is also a macroscopic concept, and is not limited to being absolutely parallel to the substrate. The inventive concept claimed by the present application is that the channel between the first plate and the second plate is a channel not perpendicular to the substrate.

In an exemplary embodiment, the semiconductor layer 23 may be of a total-surrounded type that is totally surrounded on the sidewall of the gate electrode 26, that is, the cross-section of the semiconductor layer 23 in the direction parallel to the substrate is in a shape of closed-loop. Exemplarily, the semiconductor layer 23 is annular and the annular shape is adapted to an outer contour shape of a cross-section of the gate electrode 26. Exemplarily, the gate electrode 26 has a cross-section in a square shape or the like.

In an exemplary embodiment, as shown in FIG. 1A, the stacked transistors of different layers may share one word line 40 extending along the direction perpendicular to the substrate. In an exemplary embodiment, semiconductor layers 23 corresponding to transistors of different layers may be located on a sidewall of the word line 40, and are respectively in different regions extending along the direction perpendicular to the substrate.

FIG. 1B is a cross-sectional view of a memory taken along a direction parallel to a substrate according to an exemplary embodiment. In an exemplary embodiment, as shown in FIG. 1B, memory cells of a same layer form an array distributed along the first direction D1 and a second direction D2, respectively. Each layer of the memory cells further includes a bit line 30, and the bit line 30 is connected with the second electrode 52 of a transistor of the same layer and the same column. FIG. 1B shows that each layer includes three rows and two columns of memory cells, but the embodiments of the present disclosure are not limited thereto, and each layer may include other quantity of rows and columns of memory cells, for example, each layer may include only one memory cell. The first direction D1 may be parallel to the substrate, the second direction D2 may be parallel to the substrate, and the first direction D1 and the second direction D2 intersect. In some embodiments, the first direction D1 may be perpendicular to the second direction D2.

In an exemplary embodiment, as shown in FIG. 1B, the second electrodes 52 of transistors of memory cells of two adjacent columns of a same layer are connected with the same bit line 30. The second electrodes 52 of two adjacent columns of transistors in the same layer and the bit line 30 may be in an integrated structure.

In an exemplary embodiment, as shown in FIG. 1B, the second electrode 52 of the transistor may be part of the bit line 30 to which the second electrode 52 is connected.

In an exemplary embodiment, as shown in FIG. 1B, the bit line 30 may extend along the second direction D2.

In an exemplary embodiment, as shown in FIG. 1B, the first electrode 51 may extend along the first direction D1.

FIG. 1C is a cross-sectional view of a capacitor of a semiconductor device taken along a direction perpendicular to a substrate according to an exemplary embodiment. In an exemplary embodiment, as shown in FIGS. 1A and 1C, this embodiment provides a semiconductor device including one or at least two capacitors stacked along a direction perpendicular to a substrate. The memory described above includes the semiconductor device, so that the memory is formed into a 1T1C memory cell. The capacitor may include a first plate 41, a second plate 42 and a dielectric layer 13, wherein the first plate 41 and the second plate 42 are insulated from each other, the dielectric layer 13 is located between the first plate 41 and the second plate 42, and the first plate 41 is connected with the first electrode 51 of the transistor. The first electrode 51 may be a heterogeneous conductor and may be formed integrally with the first electrode 41 or may be a conductive strip independent of the first electrode 41.

In an exemplary embodiment, as shown in FIGS. 1A and 1C, the first plate 41 includes a first body structure 411 and at least two first branch layers 81, and the first body structure 411 is located at a side of the at least two first branch layers 81 away from the second plate 42. The at least two first branch layers 81 are extended portions of the conductive layer of one material of the heterogeneous layers of the first body structure. The at least two first branch layers 81 are arranged at intervals along the direction perpendicular to the substrate 1. The first body structure 411 includes a first conductive layer 85 and a second conductive layer 84 alternately stacked along the direction perpendicular to the substrate 1, and each first branch layer 81 is an extended portion of the first conductive layer 85 or the second conductive layer 84. The first conductive layer 85 and the second conductive layer 84 are made of different materials and have different etching selectivity ratios.

The first conductive layer 85 and the second conductive layer 84 and the first branch layers 81 all extend along the direction parallel to the substrate.

The first plate 41 further includes a groove 83 located between adjacent first branch layers 81. The groove 83 extends along the direction parallel to the substrate 1, and at least part of the dielectric layer 13 and at least part of the second plate 42 are in the groove 83. An orthographic projection of the groove 83 on the substrate 1 is overlapped with an orthographic projection of the adjacent first branch layers 81 on the substrate 1, and the orthographic projection of the groove 83 and an orthographic projection of the first body structure 411 on the substrate 1 are not overlapped.

The groove is a conductor of one of the materials of the stacked heterogeneous conductive layers through transverse etching, conductive layers between the etched grooves naturally form the first branch layers, and the stacked heterogeneous conductive layers that are not etched form the body structure.

In the capacitor according to the embodiment of the present disclosure, the first branch layers 81 are arranged at intervals along the direction perpendicular to the substrate 1, and the groove 83 is located between the adjacent first branch layers 81, so that at least part of the second plate 42 is in the groove 83, thus increasing an area where the second plate 42 and the first plate 41 are facing each other and improving capacity of the capacitor.

In an exemplary embodiment, as shown in FIGS. 1A and 1C, the first body structure 411 of the first plate 41 is a heterogeneous multi-layer stacked structure, and the heterogeneity in the heterogeneous multi-layer stacked structure may be an formed of at least two heterogeneous materials by alternately stacking multiple layers. For example, material A and material B are alternately stacked, and every two layers are stacked cyclically, and the total stacked layers can be 4 layers, 6 layers, 8 layers, etc. It is also possible to alternately stacking three materials, and the total number of stacked layers can be a multiple of 3, for example, 6 or 9, etc., and the stacking is repeated once for every three layers.

Exemplarily, the first body structure 411 includes first conductive layers 85 and second conductive layers 84 which are respectively formed by two materials. The first conductive layers 85 and second conductive layers 84 are sequentially deposited and stacked. Each second conductive layer 84 is in connection or contact with adjacent first conductive layers 85, and an upper surface and a lower surface of the second conductive layer 84 are respectively in contact with the adjacent first conductive layers 85. The first branch layers 81 of the first plate 41 are connected with their corresponding first conductive layers 85, that is, a plurality of first branch layers 81 are respectively connected with a plurality of first conductive layers 85 in one-to-one correspondence.

In an exemplary embodiment, a first conductive layer 85 and a second conductive layer 84 have different etching selectivity ratios. Under a same etching condition, an etching rate of the second conductive layer 84 is greater than or much greater than an etching rate of the first conductive layer 85, so that a second conductive thin film for forming the second conductive layer 84 and a first conductive thin film for forming the first conductive layer 85 can be etched simultaneously by a same etching process, and the second conductive thin film forms the groove 83 and the second conductive layer 84. The groove 83 extends along the direction parallel to the substrate 1, the groove 83 and the second conductive layer 84 are located in a same film layer, and bottom of the groove 83 is an end face of the second conductive layer 84. The bottom of the groove is a groove bottom of the groove, and side walls on two sides of the groove bottom of the groove are side walls formed by two conductive layers, the bottom of the groove is a surface away from the groove opening in the drawing.

In an exemplary embodiment, a material type of the first conductive layer 85 includes one of the followings: metal, alloy, metal nitride, and metal oxide conductor. The material type of the second conductive layer 84 includes one of the followings: metal, alloy, metal nitride, and metal oxide conductor. The material types of the first conductive layer 85 and the second conductive layer 84 are the same or different. The metal can be a material such as Ti, W or Cu, the alloy can be an alloy of Ti and other metals, the metal nitride can be TiN, and the metal oxide conductor can be ITO or the like.

In an exemplary embodiment, in one first plate 41, in the direction perpendicular to the substrate 1, a first conductive layer 85 and a second conductive layer 84 which are adjacent have a same length in the first direction D1, and orthographic projections of the first conductive layer 85 and the second conductive layer 84 which are adjacent, on the substrate 1 are completely overlapped.

In an exemplary embodiment, as shown in FIGS. 1A and 1C, each first branch layer 81 and its corresponding first conductive layer 85 form an integrated structure, the first branch layer 81 and its corresponding first conductive layer 85 can be formed using a same first conductive thin film, that is, the first conductive thin film can be formed into the first branch layer 81 and the first conductive layer 85 by etching the first conductive thin film.

In an exemplary embodiment, as shown in FIGS. 1A and 1C, in one first plate 41, depths of the grooves 83 of different layers are the same in the direction perpendicular to the substrate 1. The depth of each groove 83 is a length of the groove 83 in the first direction D1.

In an exemplary embodiment, as shown in FIGS. 1A and 1C, in one first plate 41, in the direction perpendicular to the substrate 1, lengths of the first branch layers 81 of different layers in the first direction D1 are the same, and orthographic projections of the first branch layers 81 of different layers on the substrate 1 are completely overlapped.

In an exemplary embodiment, as shown in FIGS. 1A and 1C, the second plate 42 includes a second body structure 421 and at least two second branch layers 82 located on the second body structure 421. The at least two second branch layers 82 are arranged at intervals along the direction perpendicular to the substrate 1, at least one of the second branch layers 82 is disposed in a corresponding groove 83, filled in the groove 83, and insulated from the first plate 41 by the dielectric layer 13 positioned in the groove 83.

In an exemplary embodiment, the first plate 41 includes an upper surface and a lower surface disposed oppositely, and two side surfaces connecting the upper surface with the lower surface. The upper surface is at a side of the lower surface away from the substrate, and the two side surfaces are at opposite sides of the upper surface and the lower surface in the second direction D2. The groove 83 penetrates through a side surface of the first plate 41, and the groove 83 is on the side surface of the first plate 41 to expose a side surface of the second branch layer 82.

In an exemplary embodiment, as shown in FIGS. 1A and 1C, in one second plate 42, in the direction perpendicular to the substrate 1, lengths of the second branch layers 82 of different layers in the first direction D1 are the same, and orthographic projections of the second branch layers 82 of different layers on the substrate 1 are completely overlapped.

In an exemplary embodiment, as shown in FIGS. 1A and 1C, the second plate 42 is at a side of the first plate 41 away from the gate electrode 26. The second body structure 421 is located at a side of the second branch layers 82 away from the first plate 41. The second branch layers 82 extend into the grooves 83 through the openings of the grooves 83.

In an exemplary embodiment, as shown in FIGS. 1A and 1C, at least two capacitors are stacked at intervals in the direction perpendicular to the substrate 1. In the direction perpendicular to the substrate 1, the second body structures 421 of the second plates 42 of the adjacent capacitors are connected to form an integrated structure.

In an exemplary embodiment, as shown in FIGS. 1A and 1C, at least a part of the dielectric layer 13 is disposed between the first branch layer 81 and the second branch layer 82 which are adjacent, so as to separate the first branch layer 81 from the adjacent second branch layer 82 and insulate the first branch layer 81 and the second branch layer 82 which are adjacent from each other.

In an exemplary embodiment, as shown in FIGS. 1A and 1C, the dielectric layer 13 of one of the capacitors may be connected to form an integrated structure, and the dielectric layer 13 with the integrated structure is curved in a circuitous manner in the direction perpendicular to the substrate.

In an exemplary embodiment, as shown in FIGS. 1A and 1C, dielectric layer 13 of adjacent capacitors may be connected to form an integrated structure in the direction perpendicular to the substrate 1.

In an exemplary embodiment, the dielectric layer 13 may be a high-K dielectric material, that is, a dielectric material having a dielectric constant K≥3.9. The high-K dielectric material may include, but is not limited to, at least one of the followings: silicon oxide, aluminum oxide (Al₂O₃), hafnium oxide.

In an exemplary embodiment, as shown in FIG. 1A, a patterned insulation layer 14 is provided between adjacent capacitors in the direction perpendicular to the substrate 1, and the patterned insulation layer 14 separates adjacent capacitors from each other.

In an exemplary embodiment, at least two of the capacitors are stacked at intervals in the direction perpendicular to the substrate 1. In the direction perpendicular to the substrate 1, materials of the first conductive layers 85 of the first plates 41 of different capacitors are the same, and materials of the second conductive layers 84 of the first plates 41 of different capacitors are the same.

In an exemplary embodiment, as shown in FIG. 1A, the first body structure of the first electrode 51 of the transistor and the first plate 41 of the capacitor form an integrated structure. The first electrode 51 is an extended portion of the first body structure extending in a direction away from the second plate 42.

In an exemplary embodiment, as shown in FIG. 1B, in a cross section in the direction parallel to the substrate, the memory may further include a detection pin 61. The detection pin 61 is disposed at a side of the memory cells, and the detection pins 61 is electrically connected with the bit line 30 of the memory cells of each layer. A detection unit may be electrically connected with the detection pin 61 for inputting a detection signal to the bit lines 30 of the memory cells through the detection pin 61 to perform detection on the memory cells.

The technical scheme of this embodiment will be further explained by a manufacturing process of the semiconductor device of this embodiment. The “patterning process” in this embodiment includes film layer deposition, photoresist coating, mask exposure, development, etching, photoresist stripping and other processes, which is a mature manufacturing process in related technologies. The “photolithography process” in this embodiment includes film layer coating, mask exposure and development, and is a mature manufacturing process in the related art. The deposition may be known processes such as sputtering, evaporation, chemical vapor deposition, the coating may be known coating processes, and the etching may be known approaches, which are not specifically limited herein. In the description of the embodiment, it is understood that, a “thin film” means a thin film made of certain material on a substrate by a deposition or coating process. If the “thin film” does not need a patterning process or photolithography process during the whole manufacturing process, the “thin film” can also be called a “layer”. If the “thin film” needs a patterning process or photolithography process during the whole manufacturing process, it is called a “thin film” before the patterning process and a “layer” after the patterning process. The “layer” after the patterning process or photolithography process includes at least one “pattern”.

The semiconductor device includes one or at least two capacitors stacked in a direction perpendicular to a substrate. At least one of the capacitors includes a first plate and a second plate, and a dielectric layer between the first plate and the second plate. The first plate includes a first body structure and at least two first branch layers, and the at least two first branch layers are arranged at intervals along the direction perpendicular to the substrate. The first body structure includes a first conductive layer and a second conductive layer alternately stacked along the direction perpendicular to the substrate. A method for manufacturing the semiconductor device includes:
providing a substrate, and forming a first conductive thin film and a second conductive thin film arranged alternately in sequence on the substrate;
etching and removing a part of the second conductive thin film in a direction parallel to the substrate, forming the retained second conductive thin film into a second conductive layer, and forming the part of the second conductive thin film that has been etched and removed into a groove, wherein the groove extends along a direction parallel to the substrate;
forming a part of the first conductive thin film into a first branch layer, wherein the groove is located between adjacent first branch layers; forming a part of the first conductive thin film into a first conductive layer;
forming a dielectric layer, wherein at least a part of the dielectric layer is formed on an inner wall of the groove; and
forming a second plate, wherein at least a part of the second plate is located in the groove.

In an exemplary embodiment, grooves of the capacitors of different layers are formed by a single etching process in the direction perpendicular to the substrate.

In an exemplary embodiment, the first conductive thin film and the second conductive thin film have different etching selectivity ratios.

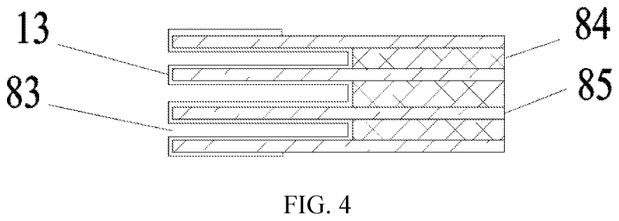

In an exemplary embodiment, the method for manufacturing the semiconductor device includes:
Step 101: sequentially depositing a first conductive thin film 91 and a second conductive thin film 92 arranged alternately on a substrate by an atomic deposition process, as shown in FIG. 2;
Step 102: etching and removing a part of the second conductive thin film along a direction parallel to the substrate by an etching process on the basis of the substrate 1 where the aforementioned pattern is formed, retaining a part of the second conductive thin film, forming the retained second conductive thin film into a second conductive layer 84, and forming the part of the second conductive thin film that has been etched and removed into a groove 83, wherein the groove 83 extends along the direction parallel to the substrate; forming a part of the first conductive thin film into a first branch layer 81, wherein the groove 83 is located between adjacent first branch layers 81 and an orthographic projection of the groove 83 is overlapped with orthographic projections of the adjacent first branch layers 81 on the substrate; forming a part of the first conductive thin film into a first conductive layer 85, wherein orthographic projections of the first conductive layer 85 and the second conductive layer 84 on the substrate are overlapped, as shown in FIG. 3.
Step 103: depositing a high-K insulation thin film on an inner wall of the groove 83 by an atomic deposition process on the substrate 1 where the aforementioned patterns are formed, forming the high-K insulation thin film into a dielectric layer 13, wherein the dielectric layer 13 covers the inner wall (side walls and bottom wall) of the groove 83 and side walls of the first branch layer 81, as shown in FIG. 4.
Step 104: forming a second plate 42 on the substrate 1 where the aforementioned patterns are formed.

Forming the second plate 42 includes: depositing a third conductive thin film on the dielectric layer 13, filling at least a part of the third conductive thin film in the groove 83, forming the part of the third conductive thin film filled in the groove 83 into a second branch layer 82, and forming a part of the third conductive thin film located outside the groove 83 into a second body structure 421, as shown in FIG. 1C.

The scheme provided by the embodiment simplifies the process flow, is easy to implement, improves a production efficiency, and has advantages of easy process implementation, low production cost, high yield and the like.

An embodiment of the disclosure also provides an electronic equipment, which includes the memory described in any one of the foregoing embodiments. The electronic equipment can be a storage device, a smart phone, a computer, a tablet computer, an artificial intelligence device, a wearable device or a mobile power supply, etc. The storage device may include a memory in a computer or the like, and this is not restricted here.

Although implementations disclosed in the present disclosure are as described above, the described contents are only implementations used for facilitating understanding of the present disclosure, but are not intended to limit the present disclosure. Without departing from the spirit and scope disclosed in the present disclosure, any person skilled in the art to which the present disclosure pertains may make any modification and change in the form and details of implementation, but the scope of patent protection of the present disclosure shall still be defined by the appended claims.

1. semiconductor device, comprising:
one or at least two capacitors stacked along a direction perpendicular to a substrate;
wherein at least one of the capacitors comprises 5 a first plate and a second plate, and a dielectric layer between the first plate and the second plate;
the first plate comprises a first body structure and at least two first branch layers, wherein the at least two first branch layers are arranged at intervals along the direction perpendicular to the substrate, the first body structure comprises a first conductive layer and a second conductive layer alternately stacked along the direction perpendicular to the substrate, the first plate further comprises a groove located between adjacent first branch layers, the groove extends along a direction parallel to the substrate, and at least part of the dielectric layer and at least part of the second plate are located in the groove.

2. The semiconductor device according to claim 1, wherein materials of the first conductive layer and the second conductive layer are different, the second conductive layer is connected with adjacent first conductive layers, and the first branch layers are connected with the first conductive layers.

3. The semiconductor device according to claim 2, wherein the first conductive layer and the second conductive layer have different etching selectivity ratios;
the first branch layers and the first conductive layer form an integrated structure;
the groove and the second conductive layer are located in a same film layer, and bottom of the groove is an end face of the second conductive layer.

4. The semiconductor device according to claim 3, wherein depths of grooves in different layers are the same in the first plate.

5. The semiconductor device according to claim 1, wherein the second plate comprises a second body structure and at least two second branch layers located on the second body structure, the at least two second branch layers are arranged at intervals along the direction perpendicular to the substrate, at least one of the second branch layers is disposed in a corresponding groove to fill the groove.

6. The semiconductor device according to claim 5, wherein the first plate comprises an upper surface and a lower surface that are oppositely disposed, and two side surfaces connecting the upper surface with the lower surface, the groove penetrates through a side surface of the first plate, the groove is on the side surface of the first plate to expose a side surface of the second branch layer.

7. The semiconductor device according to claim 1, wherein at least two of the capacitors are stacked at intervals in the direction perpendicular to the substrate; in the direction perpendicular to the substrate, second plates of adjacent capacitors are connected to form an integrated structure.

8. The semiconductor device according to claim 1, wherein at least two of the capacitors are stacked at intervals in the direction perpendicular to the substrate; in the direction perpendicular to the substrate, materials of the first conductive layers of the first plates of different capacitors are the same, and materials of the second conductive layers of the first plates of the different capacitors are the same.

9. The semiconductor device according to claim 1, wherein a material type of the first conductive layer comprises one of the followings: metal, alloy, metal nitride and metal oxide conductor; a material type of the second conductive layer comprises one of the followings: metal, alloy, metal nitride, and metal oxide conductor.

10. A memory, comprising the semiconductor device according to claim 1.

11. The memory according to claim 10, comprising a memory cell of single-layer or a memory cell of a plurality of stacked layers, and the memory cell comprises a transistor, the transistor comprises a first electrode, and a capacitor of the semiconductor device is connected with the first electrode of the transistor.

12. The memory according to claim 11, wherein the first electrode and the first body structure of the first plate of the capacitor form an integrated structure.

13. The memory according to claim 12, wherein the first electrode is an extended portion of the first body structure extending in a direction away from the second plate.

14. The memory according to claim 11, wherein the transistor further comprises a second electrode, a gate electrode and a semiconductor layer, the gate electrode extends along the direction perpendicular to the substrate, the semiconductor layer surrounds the gate electrode and is insulated from the gate electrode, the first electrode and the second electrode are arranged at interval on the semiconductor layer, and the semiconductor layer comprises a channel extending along the direction parallel to the substrate.

15. An electronic equipment, comprising the memory according to claim 10.

16. A method for manufacturing a semiconductor device, wherein the semiconductor device comprises one or at least two capacitors stacked in a direction perpendicular to a substrate; at least one of the capacitors comprises a first plate and a second plate, and a dielectric layer between the first plate and the second plate; the first plate comprises a first body structure and at least two first branch layers, the at least two first branch layers are arranged at intervals along the direction perpendicular to the substrate, the first body structure comprises a first conductive layer and a second conductive layer alternately stacked along the direction perpendicular to the substrate; the method for manufacturing the semiconductor device comprises:
providing a substrate, sequentially forming a first conductive thin film and a second conductive thin film arranged alternately on the substrate, wherein the first conductive thin film and the second conductive thin film have different etching selectivity ratios;
etching and removing a part of the second conductive thin film in a direction parallel to the substrate, forming the retained second conductive thin film into the second conductive layer, and forming the part of the second conductive thin film that has been etched and removed into a groove, wherein the groove extends along a direction parallel to the substrate;
forming a part of the first conductive thin film into the first branch layers, wherein the groove is located between adjacent first branch layers; forming a part of the first conductive thin film into a first conductive layer;
forming a dielectric layer, wherein at least a part of the dielectric layer is formed on an inner wall of the groove; and
forming a second plate, wherein at least a part of the second plate is located in the groove.

17. The method for manufacturing a semiconductor device according to claim 16, wherein grooves of capacitors of different layers 5 are formed by a single etching process in the direction perpendicular to the substrate.
